(19) United States
(12) Patent Application Publication
(10) Pub. No.: US 2017/0133334 A1
(43) Pub. Date: May 11, 2017

(54) SEMICONDUCTOR DEVICE AND MANUFACTURING METHOD THEREOF

(71) Applicant: Amkor Technology, Inc., Tempe, AZ (US)

(72) Inventors: Do Hyung Kim, Seongnam-si (KR); Young Suk Chung, Seoul (KR); Seung Chul Han, Uijeongbu-si (KR); Jung Soo Park, Seongnam-si (KR)

(21) Appl. No.: 14/935,912

(22) Filed: Nov. 9, 2015

(51) Int. Cl. H01L 23/00; H01L 21/56; H01L 23/31

(52) U.S. Cl. CPC H01L 24/05; H01L 23/3157; H01L 21/568; H01L 2224/0401; H01L 2224/02371; H01L 2224/0231

(57) ABSTRACT

A semiconductor device and a manufacturing method thereof, which can reduce a number of manufacturing processes and/or can reduce a thickness of the semiconductor device. As a non-limiting example, various aspects of this disclosure provide for the elimination process steps and/or a reduction in package size based on dielectric layer characteristics.

### CROSS-REFERENCE TO RELATED APPLICATIONS/INCORPORATION BY REFERENCE

[Not Applicable].

### FEDERALLY SPONSORED RESEARCH OR DEVELOPMENT

[Not Applicable]

### SEQUENCE LISTING

[Not Applicable]

### MICROFICHE/COPYRIGHT REFERENCE

[Not Applicable]

### BACKGROUND

Field

The present invention relates to a semiconductor device and a manufacturing method thereof.

Description of the Related Art

In general, a wafer level chip size package and/or other package types may comprise a redistribution layer, which is formed on a semiconductor die and a surface of an encapsulant layer. Since it may be difficult to form the redistribution layer directly on the surface of the encapsulant layer, a dielectric layer (e.g., a passivation layer) may be first formed on the semiconductor die and on the surface of the encapsulant layer, followed by formation of the redistribution layer on the dielectric layer.

In instances where the dielectric layer is formed to cover bond pads, photo/etch processes may be performed to expose the bond pad to the outside (e.g., through the dielectric layer). In addition, since the dielectric layer may be formed on the semiconductor die and on the surface of the encapsulant layer, the overall thickness of the completed semiconductor device may be unnecessarily large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

The accompanying drawings are included to provide a further understanding of the present disclosure, and are incorporated in and constitute a part of this specification. The drawings illustrate examples of the present disclosure and, together with the description, serve to explain various principles of the present disclosure. In the drawings:

FIGS. 1A to 1H show cross-sectional views illustrating a semiconductor device and a method of manufacturing thereof, in accordance with various aspects of the present disclosure;

FIG. 2 shows a cross-sectional view illustrating a semiconductor device and method of manufacturing thereof, in accordance with various aspects of the present disclosure; and

FIG. 3 shows a cross-sectional view illustrating a semiconductor device and manufacturing method thereof, in accordance with various aspects of the present disclosure.

### SUMMARY

Various aspects of the present disclosure provide a semiconductor device and a manufacturing method thereof, which can reduce a number of manufacturing processes and/or can reduce a thickness of the semiconductor device. As a non-limiting example, various aspects of this disclosure provide for the elimination of process steps and/or a reduction in package size based on dielectric layer characteristics.

### DETAILED DESCRIPTION OF VARIOUS ASPECTS OF THE DISCLOSURE

The following discussion presents various aspects of the present disclosure by providing various examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.”

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “lower,” “side,” and the like, may be used in distinguishing one element from another element in a relative manner. It should be understood, however, that components may be oriented in different manners, for example a semiconductor device may be turned sideways so that its “top” surface is facing horizontally and its “side” surface is facing vertically, without departing from the teachings of the present disclosure.

According to various aspects of the present disclosure, there is provided a method of manufacturing a semiconductor device, including providing or preparing a carrier, providing a semiconductor die including a first surface, a second surface opposite to the first surface, and at least a third surface extending between the first surface and the second surface, attaching the first surface of the semiconductor die to the carrier, forming a first dielectric layer (e.g., a passivation layer) on the second and third surfaces of the semiconductor die and a portion of the carrier not attached to the semiconductor die, forming an encapsulant layer on the first dielectric layer, removing the carrier to expose the first surface of the semiconductor die and the area of the first dielectric layer formed on the portion of the carrier not attached to the semiconductor die (or not covered by the semiconductor die), and forming a conductive layer (e.g., a redistribution layer) on the first surface of the semiconductor die and the area of the first dielectric layer formed on the portion of the carrier not attached to the semiconductor die.

Also, according to various aspects of the present disclosure, there is provided a semiconductor device including a semiconductor die including a first surface, a second surface opposite to the first surface, and at least a third surface extending between the first surface and the second surface, a first dielectric layer (e.g., a passivation layer) formed on the second and third surfaces of the semiconductor die and comprising a portion extending outwardly from the semiconductor die and coplanar with the first surface of the semiconductor die, an encapsulant layer formed on the first dielectric layer, and a conductive layer (e.g., a redistribution layer) formed on the first surface of the semiconductor die and the portion of the first dielectric layer extending outwardly from, and coplanar with, the first surface of the semiconductor die.

Various aspects of the present disclosure may, for example, provide a semiconductor device and a manufacturing method thereof, which can reduce the number of processes (e.g., photo/etch processes) and/or reduce a thickness of the semiconductor device. As an example, after forming a first dielectric layer (e.g., a passivation layer) on a top surface and lateral surfaces of a semiconductor die and in the vicinity of the lateral surfaces of the semiconductor die, an encapsulation layer is formed, and a conductive layer is then formed on a bottom surface of the semiconductor die and in the vicinity of (e.g., on) the bottom surface of the first dielectric layer. For example, various photo/etch processes for exposing the bond pads of the semiconductor die to the outside may be skipped, and the conductive layer may be directly formed on the bottom surface of the semiconductor die and on the first dielectric layer, thereby simplifying the manufacturing method of the semiconductor device.

In addition, according to various aspects of the present disclosure, the first dielectric layer might not be formed on the bottom surface of the semiconductor die, but formed in the vicinity of a lateral portion (or side) of the semiconductor die, so that the encapsulant layer might not be exposed at a bottom portion. Accordingly, the conductive layer may be directly formed on the semiconductor die and the first dielectric layer, which may reduce the thickness of the semiconductor device. For example, since the first dielectric layer may be formed on the lateral (or side) portion of the semiconductor die and extending laterally from the lateral portion of the semiconductor die, rather than for example on the bottom surface of the semiconductor die, the overall thickness of the semiconductor device may be reduced.

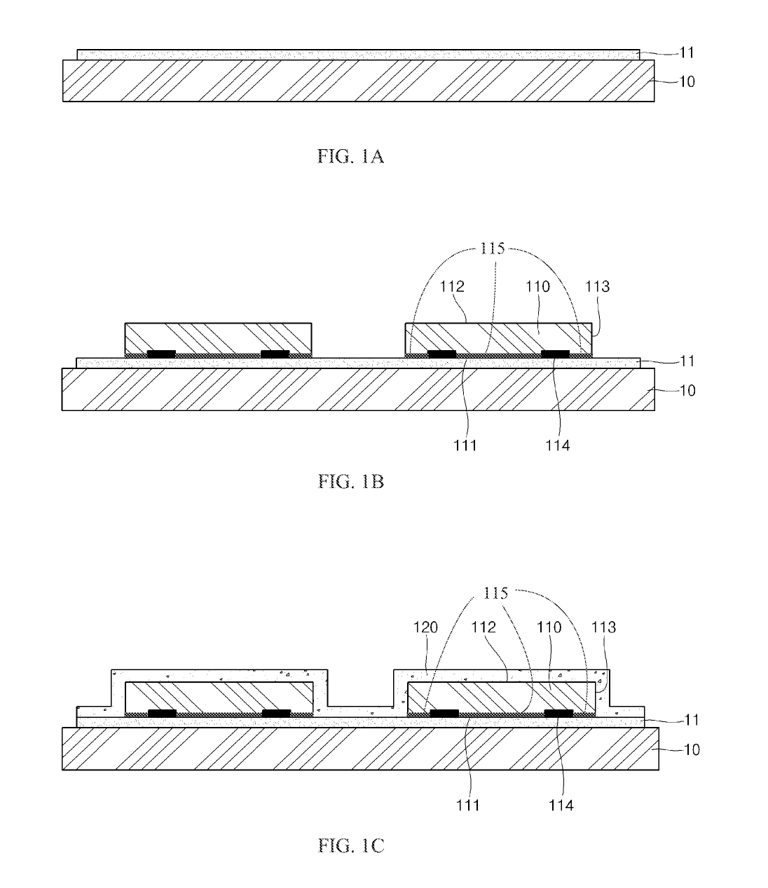

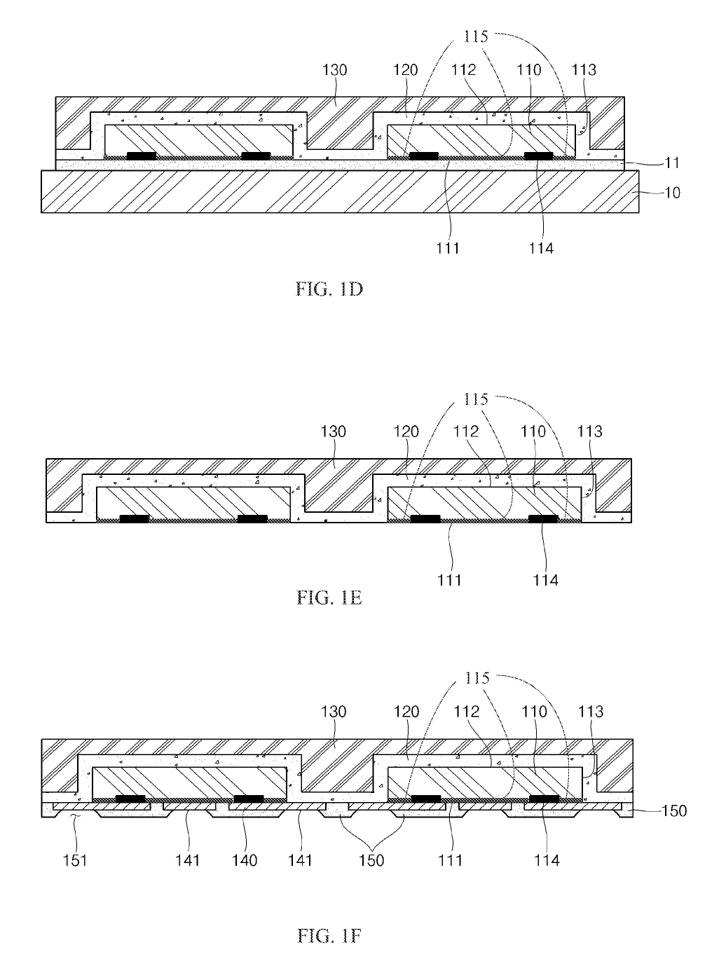

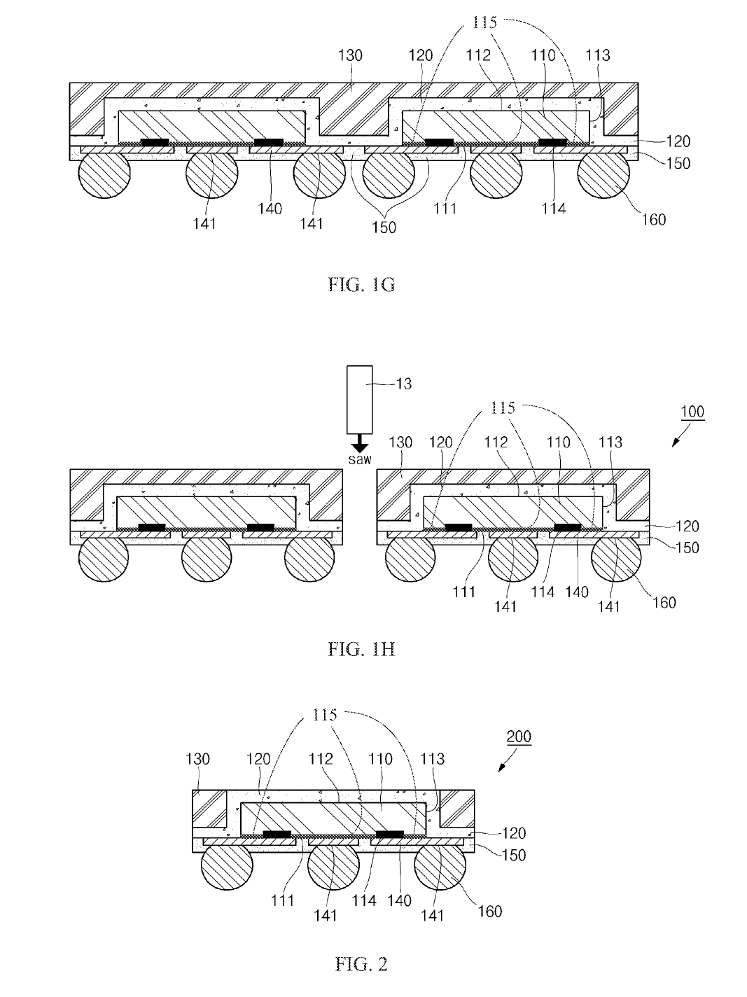

Referring to FIGS. 1A to 1H, cross-sectional views illustrating a semiconductor device and a manufacturing method thereof 100, in accordance with various aspects of the present disclosure are illustrated.

The method may, for example, comprise preparing a carrier 10, adhering one or more semiconductor die 110, forming a first dielectric layer 120 (e.g., a passivation layer), forming an encapsulant layer 130, removing the carrier 10, forming a conductive layer 140 (e.g., a redistribution layer) and forming conductive bumps 160.

As illustrated in FIG. 1A, in the preparing (or providing) of the carrier 10, the carrier 10, for example shaped of a substantially planar panel, is prepared (or provided). The carrier 10 may, for example, be made of one or more of stainless steel, glass, dummy wafer material (e.g., a silicon substrate on which electronic devices have not been fabricated), porous ceramic, equivalents thereof, etc., but aspects of the present invention are not limited thereto.

For example, a temporary adhesive layer 11 having a thickness (e.g., a predetermined thickness determined before the forming thereof) may be formed on a top surface of the carrier 10. The temporary adhesive layer 11 may be formed in any of a variety of manners, non-limiting examples of which are provided herein. For example, the temporary adhesive layer 11 may be formed by one or more of: screen printing, taping, spin coating, spray coating and equivalents thereof, but the scope of the present disclosure is not limited thereto. The temporary adhesive layer 11 may, for example, be formed at a relatively low cost.

Examples of the temporary adhesive layer 11 may, for example, comprise TZNR-series thermoplastic temporary adhesives commercially available from TOK Co., Ltd., HT-series thermoplastic temporary adhesives commercially available from Brewer Science Inc., etc.

As illustrated in FIG. 1B, in the adhering of the one or more semiconductor die 110, the semiconductor die 110 is/are adhered on the adhesive layer 11 formed on the carrier 10. For example, each of the semiconductor die 110 may comprise, for example, a planar first surface 111, a planar second surface 112 opposite to the first surface 111, at least a third surface 113 extending between the first surface 111 and the second surface 112, a plurality of bond pads 114 formed on the first surface 111, and/or a dielectric layer 115 formed on the first surface 111. Dielectric layer 115 may be referred to as a passivation layer or as a die dielectric layer.

The semiconductor die 110 may, for example, comprise a native and/or manmade dielectric layer 115 on the first surface 111 of the semiconductor die 110. The dielectric layer 115 may, for example, expose the bond pads 114 through apertures formed therein. The dielectric layer 115 may comprise any of a variety of materials, non-limiting examples of which are provided herein. For example, the dielectric layer 115 may comprise an inorganic dielectric layer (e.g., silicon dioxide, silicon nitride, silicon oxide, etc.) and/or an organic dielectric layer. The dielectric layer 115 may, for example, be formed by any of a variety of processes, non-limiting examples of which are provided herein. For example, the dielectric layer 115 may be formed by one or more of thermal oxidation, a chemical vapor deposition (CVD) process, etc.

For example, the first surface 111 may correspond to a bottom surface of the semiconductor die 110, the second surface 112 may correspond to a top surface of the semiconductor die 110 and the third surface 113 may correspond to one or more of opposite side or lateral surfaces of the semiconductor die 110. For example, the first surface 111 of the semiconductor die 110 (e.g., comprising the bond pads 114 and/or the dielectric layer 115) may be temporarily adhered to the adhesive layer 11 provided on the carrier 10.

The semiconductor die 110 may, for example, be formed (e.g., placed) on the carrier 10 in a matrix configuration. For example, a plurality of semiconductor die 110 may be arranged on the carrier 10 spaced a regular interval apart from each other. According to various aspects of the present disclosure, the semiconductor device 100 may be manufactured in large quantities, which may reduce the manufacturing cost. In FIG. 1B, two semiconductor die 110 temporarily adhered on the carrier 10 are illustrated, but aspects of the present invention are not limited thereto. Several tens to several hundreds to several thousands of semiconductor die 110 may be temporarily adhered on the carrier 10.

As illustrated in FIG. 1C, in the forming of the first dielectric layer 120 (e.g., a passivation layer), the first dielectric layer 120 having a thickness (e.g., a predetermined thickness determined prior to the formation thereof, for example a target thickness) may be formed on the second and third surfaces 112 and 113 of the semiconductor die 110 and on a portion of the carrier 10 not attached to (or not covered by) the semiconductor die 110. For example, the first dielectric layer 120 may be formed not only on (e.g., directly on) the second and third surfaces 112 and 113 of the semiconductor die 110 but also on (e.g., directly on) the adhesive layer 11 disposed at portions of the carrier 10 that are not attached to (or not covered by) the semiconductor die 110. Therefore, the first dielectric layer 120 may have a cross section having a square-wave shape or a serrated-wave shape, but aspects of the present invention are not limited thereto.

The first dielectric layer 120 (e.g., a semiconductor passivation layer, a protective layer formed on semiconductor material, etc.) may be formed in any of a variety of manners, non-limiting examples are provided herein. For example, the first dielectric layer 120 may be formed by using one or more methods comprising screen printing, spin coating, spray coating, plasma-enhanced chemical vapor deposition (PECVD), equivalents thereof, etc., but aspects of the present invention are not limited thereto. The first dielectric layer 120 may comprise various dimensional characteristics. For example, the dielectric layer 120 may comprise a uniform thickness throughout For example, in an example implementation in which PECVD is utilized to form the first dielectric layer 120, the first dielectric layer 120 may, for example, have a thickness in the 0.2 um to 1.0 um range. Also for example, in an example implementation, the first dielectric layer 120 may have a thickness less than a thickness of the semiconductor die 110, less than half a thickness of the semiconductor die 110, etc.

The first dielectric layer 120 may comprise, for example, one or more of the following: bismaleimidetriazine (BT), phenolic resin, polyimide (PI), benzo cyclo butene (BCB), poly benz oxazole (PBO), epoxy and equivalents thereof and compounds thereof, but aspects of the present disclosure are not limited thereto. Also for example, the first dielectric layer 120 may comprise one or more of the following: a silicon oxide layer, a silicon nitride layer and an equivalent thereof, but aspects of the present disclosure are not limited thereto. An inorganic layer of the first dielectric layer 120 may, for example, be formed by one or more methods comprising: chemical vapor deposition (CVD), physical vapor deposition (PVD), equivalents thereof, etc.

As illustrated in FIG. 1D, in the forming of the encapsulant layer 130, the encapsulant layer 130 is formed on (e.g., directly on) the first dielectric layer 120. For example, as described above, the encapsulant layer 130 having a thickness (e.g., a first thickness generally above the semiconductor die 110 and a second thickness between semiconductor die 110), which may for example be different from the first thickness, may be formed on the first dielectric layer 120 having a square-wave or serrated-wave cross-sectional shape (e.g., on a bottom surface thereof). For example, the encapsulant layer 130 may be formed on the second and third surfaces 112 and 113 of the semiconductor die 110 (e.g., on the dielectric layer 120 formed on such second and third surfaces 112 and 113) and the first dielectric layer 120 formed on the adhesive layer 11 disposed at portions of the carrier 10 that are not attached to (or covered by) the semiconductor die 110 to a thickness (e.g., a predetermined thickness determined before formation thereof). A top surface of the encapsulant layer 130 may, for example, be formed to be planar (e.g., substantially planar or perfectly planar).

The encapsulant layer 130 may be formed in any of a variety of manners, non-limiting examples of which are presented herein. For example, the encapsulant layer 130 may be formed by a general transfer molding process using a mold (e.g., by compression molding, injection molding, etc.), a dispensing process using a dispenser, etc. In addition, the encapsulant layer 130 may comprise any of a variety of materials, non-limiting examples of which are provided herein. For example, the encapsulant layer 130 may be made of, or comprise, an epoxy molding compound including a filler, an epoxy resin, a curing agent, and a flame retardant material, and equivalents thereof, but aspects of the present invention are not limited thereto.

As illustrated in FIG. 1E, in the removing of the carrier 10, the carrier 10 and the adhesive layer 11 are removed from the first surface 111 of the semiconductor die 110 and from the first dielectric layer 120 disposed on a portion of the carrier 10 not attached to (or covered by, or outside the footprint of) the semiconductor die 110, thereby allowing the first surface 111 of the semiconductor die 110 and an area of the first dielectric layer 120 formed on the portion of the carrier 10 not attached to (or covered by, or outside the footprint of) the semiconductor die 110 to be exposed to the outside.

As an example, heat or light may be applied to the adhesive layer 11 to eliminate or reduce an adhesive force and/or or an etchant solution may be provided to the adhesive layer 11 to remove the adhesive layer 11. In the latter case, the carrier 10 may, for example be formed of a porous ceramic to allow the etchant solution to rapidly reach the adhesive layer 11. For example, the carrier 10 and the adhesive layer 11 may be physically stripped from the semiconductor die 110 and the first dielectric layer 120. The removal may also comprise laser-assisted debonding.

In such a manner, the first surface 111 of the semiconductor die 110 (e.g., the bond pads 114 and/or dielectric layer 115 formed thereon) and the bond pads 114 and the first dielectric layer 120 disposed laterally outside of the footprint of the semiconductor die 110 (e.g., between adjacent ones of the semiconductor die 110 and laterally outside of the semiconductor die 110) may be exposed to the outside.

In addition, in various example implementations, as a result of removing the carrier 10 and the adhesive layer 11, the first surface 111 of the semiconductor die 110 (e.g., the bond pads 114 and/or dielectric layer 115 formed thereon) and the first dielectric layer 120 (e.g., a lower surface thereof) disposed laterally outside the footprint of the semiconductor die 110 may be coplanar (e.g., substantially or perfectly coplanar). In other words, there might be no step difference between the first surface 111 of the semiconductor die 110 and the bottom surface of the first dielectric layer 120. For example, unlike in a process in which the first dielectric layer 120 is directly formed on the first surface 111 of the semiconductor die 110, in various examples in accordance with the present disclosure, the first dielectric layer 120 may be formed to outwardly lengthwise extend (or laterally extend) from the third surface 113 of the semiconductor die 110. Accordingly, the first dielectric layer 120 need not result in an increase in the thickness of the semiconductor device 100 (e.g., by adding thickness to the thickness of the semiconductor die 110).

As illustrated in FIG. 1F, in the forming of the conductive layer 140 (e.g., a redistribution layer), the conductive layer 140 may be formed on the first surface 111 of the semiconductor die 110 and the area of the first dielectric layer 120 formed on the portion of the carrier 10 not attached to (or not covered by, or outside the footprint of) the semiconductor die 110. For example, one end of a respective conductive trace of the conductive layer 140 may be connected to a respective one of the bond pads 114 provided on the first surface 111 of the semiconductor die 110, and the other end of the respective conductive trace of conductive layer 140 may be formed to extend beyond the lateral footprint of the semiconductor die 110 to (and/or under) the first dielectric layer 120 outwardly lengthwise (or laterally) extending from the third surface 113 of the semiconductor die 110. In other words, the conductive layer 140 may be formed on the first surface 111 of the semiconductor die 110 (e.g., on the bond pads 114 and/or the dielectric layer 115 formed thereon) and the bond pads 114 and on the first dielectric layer 120 outwardly lengthwise (or laterally) extending from the third surface 113 of the semiconductor die 110. As explained herein, the first surface 111 of the semiconductor die 110 may comprise a dielectric layer 115 (e.g., a native and/or manmade dielectric layer) formed prior to placement of the die 110 on the carrier 10. Such a dielectric layer 115 may, for example, provide an insulation barrier between a conductive trace of the conductive layer 140 and conductive or semi-conductive material at the first surface 111 of the semiconductor die 110. There may, for example, be apertures formed in the dielectric layer 115 to expose the bond pads 114. In such a configuration, conductive material of the conductive layer 140 may be formed directly on the dielectric material 115, the bond pads 114 and/or the dielectric layer 120 (e.g., directly on a bottom surface thereof).

As described herein, since the first surface 111 of the semiconductor die 110 and the bottom surface of the first dielectric layer 120 may be coplanar and there might be no vertical step difference therebetween, the conductive layer 140 (e.g., conductive traces thereof) may be formed coplanar with the first surface 111 of the semiconductor die 110 and lower surface of the first dielectric layer 120 without having a step difference.

The conductive layer 140 (e.g., a redistribution layer) may be formed in any of a variety of manners, non-limiting examples of which are provided herein. For example, the conductive layer 140 may be formed through the following steps: forming, for example by plating, a seed layer made of tungsten (W) or tungsten titanium (WTi) on the first surface 111 of the semiconductor die 110 (e.g., including the bond pads 114 and/or the dielectric layer 115 formed thereof) and the bond pads 114 and on the first dielectric layer 120 outwardly lengthwise (or laterally) extending from the third surface 113 of the semiconductor die 110; forming the conductive layer 140 made of copper (Cu) on the seed layer to a relatively large thickness (e.g., a large thickness relative to the seed layer) by plating (e.g., by sputtering); and patterning the conductive layer 140 through photo/etch processes in a desired pattern (e.g., a pattern of conductive traces). The conductive layer 140 may be formed having any of a variety of dimensional characteristics. By way of example and not limitation, the conductive layer 140 may be formed to have a thickness of 3 um or less, a trace width of 5 um or less, and a pitch (or spacing between trace centers) of 5 um or less.

Also, a second dielectric layer 150 (e.g., a passivation layer) may be further formed on the conductive layer 140, the first surface 111 of the semiconductor die 110 and the first dielectric layer 120 outwardly lengthwise (or laterally) extending from the third surface 113 of the semiconductor die 110, thereby protecting the conductive layer 140 from an external environment.

In addition, a plurality of openings 151 may be formed in the second dielectric layer 150, and lands 141 to which the conductive bumps 160 (or other conductive structures) are to be connected in a subsequent process may be exposed to the outside through the openings 151. The lands 141 may, for example, be exposed portions of the conductive layer 140.

The second dielectric layer 150 may be formed in any of a variety of manners, non-limiting examples of which are provided herein. For example, the second dielectric layer 150 may be formed by using one or more methods comprising: screen printing, spin coating, spray coating and equivalents thereof, but aspects of the present invention are not limited thereto.

The second dielectric layer 150 may comprise any of a variety of materials, non-limiting examples of which are provided herein. For example, the second dielectric layer 150 may comprise one or more of the following: bismaleimidetriazine (BT), phenolic resin, polyimide (PI), benzo cyclo butene (BCB), poly benz oxazole (PBO), epoxy and equivalents thereof and compounds thereof, but aspects of the present disclosure are not limited thereto. Also for example, the second dielectric layer 150 may comprise one or more of the following: a silicon oxide layer, a silicon nitride layer and an equivalent thereof, but aspects of the present disclosure are not limited thereto. An inorganic layer of the second dielectric layer 150 may, for example, be formed by using one or more methods comprising: chemical vapor deposition (CVD), physical vapor deposition (PVD), equivalents thereof, etc. Note that the second dielectric layer 150 may comprise the same or different material as the first dielectric layer 120 and/or may be formed by the same or different method.

As described here, according to various aspects of the present disclosure, the conductive layer 140 may be directly formed on the first surface 111 of the semiconductor die 110 (e.g., on a bond pad 114 and/or dielectric layer 115 thereof). That is to say, unlike in a process in which a dielectric layer is formed on both a first surface of a semiconductor die and a bottom surface of an encapsulant layer, photo/etch processes are applied to the dielectric layer to expose a bond pad from the semiconductor die to the outside, and a conductive layer is then formed on the dielectric layer, in various examples of the present disclosure, the conductive layer 140 may be directly formed on a surface of the semiconductor die 110 without the forming and/or patterning of such dielectric layer.

Therefore, according to various aspects of the present disclosure, a number of processes (e.g., photo/etch processes) can be reduced. In addition, according to various aspects of the present disclosure, only a single additional dielectric layer (e.g., the second dielectric layer 150), instead of two additional dielectric layers is formed on both the first surface of the semiconductor die, thereby reducing the thickness of the semiconductor device.

As illustrated in FIG. 1G, in the forming of the conductive bumps 160, spherical conductive bumps 160 are connected to the lands 141 of the conductive layer 140 (e.g., a redistribution layer) exposed to the outside through the openings 151. Accordingly, the conductive bumps 160 are configured to outwardly protrude from the second dielectric layer 150. Though conductive bumps in the form of spherical balls are illustrated, the conductive bumps may comprise characteristics of any of a variety of different types of conductive structures (e.g., semiconductor package attachment structures). Depending on the nature of the conductive structure, an under bump metal may be performed on the lands 141 prior to formation of the conductive structure. In an example implementation, a conductive structure comprising a solder ball may be connected to the lands 141 without forming an under bump metal.

The conductive bumps 160 may be formed in any of a variety of manners, non-limiting examples of which are provided herein. For example, the conductive bumps 160 may be formed and/or connected in the following manner. After volatile flux is applied to the lands 141, the conductive bumps 160 in a solid phase are temporarily connected on the volatile flux. Thereafter, a reflow temperature of approximately 150 degrees centigrade° C. to approximately 250 degrees centigrade° C. is applied, thereby volatilizing the flux for removal and melting the conductive bumps 160 to then be directly connected to the lands 141. Here, the conductive bumps 160 are made to be roughly spherical by surface tension and then cooled to return to a solid phase.

The conductive bumps 160 may comprise any of a variety of materials, non-limiting examples of which are provided herein. For example, the conductive bumps 160 may comprise one or more of the following: eutectic solder (Sn₃₇Pb), high lead solder (Sn₉₅Pb), lead-free solder (SnAg, SnAu, SnCu, SnZn, SnZnBi, SnAgCu, SnAgBi, etc.) and equivalents thereof, but aspects of the present invention are not limited thereto.

In an example scenario in which a plurality of semiconductor devices are being produced on a panel (e.g., a wafer, a square matrix, etc.), various aspects of this disclosure provide for singulating the panel. Such singulating (e.g., sawing, cutting, etc.) may be performed in any of a variety of manners, non-limiting examples of which are provided herein. For example, as illustrated in FIG. 1H, in the sawing (or singulating), the sawing may be performed sequentially on the encapsulant layer 130, the first dielectric layer 120 and the second dielectric layer 150 in that order or sequentially on the second dielectric layer 150, the first dielectric layer 120 and the encapsulant layer 130 in that order, thereby providing a discrete semiconductor device 100. For example, opposite ends (e.g., lateral surfaces) of each of the encapsulant layer 130, the first dielectric layer 120 and the second dielectric layer 150 may all be coplanar. For example, the sawing may be performed using one or more of a diamond blade 13, a laser beam and equivalents thereof, etc., but aspects of the present disclosure are not limited thereto.

As described above, various aspects of the present disclosure provide the semiconductor device 100 and the manufacturing method thereof, which can reduce the number of manufacturing processes and/or reduce a thickness of the semiconductor device. As an example, after forming the first dielectric layer 120 on the second and third surfaces 112 and 113 of the semiconductor die 110 and in the vicinity of the third surface 113 of the semiconductor die 110 (e.g., extending laterally outward from a footprint of the semiconductor die 110), the encapsulant layer 130 is then formed, the conductive layer 140 is then directly formed on the first surface 111 of the semiconductor die 110 (e.g., comprising bond pads 114 and/or a dielectric layer 115) and on the first dielectric layer 120 formed in vicinity of the third surface 113 of the semiconductor die 110. For example, various processes (e.g., photo/etch processes for exposing the bond pads 114 of the semiconductor die 110 to the outside) may be skipped, and the conductive layer 140 may be directly formed on the bottom surface 111 of the semiconductor die 110 and on the first dielectric layer 120, thereby simplifying the manufacturing method of the semiconductor device 100.

In addition, according to various aspects of the present disclosure, the first dielectric layer 120 might not be formed on the first surface 111 of the semiconductor die 110, but may instead be formed lengthwise (e.g., extending laterally) in the vicinity of the exterior side of the third surface 113 of the semiconductor die 110 (e.g., outside the footprint of the semiconductor die 110), so that the encapsulant layer 130 is not exposed at a bottom portion. Then the conductive layer 140 may be formed on (e.g., directly on) the semiconductor die 110 and the first dielectric layer 120. Accordingly, the thickness of the semiconductor device 100 may be reduced (e.g., relative to implementations in which an additional dielectric layer is formed on both the semiconductor die 110 and the encapsulant layer 130). For example, since the first dielectric layer 120 might not be formed on the first surface 111 of the semiconductor die 110, the thickness of the semiconductor device 100 may be reduced in relation to other implementations.

Further, in accordance with various aspects of the present disclosure, since the second and third surfaces 112 and 113 of the semiconductor die 110 may be completely surrounded by the first dielectric layer 120 and the encapsulant layer 130 may be formed on the first dielectric layer 120, it is possible to prevent impurities (e.g., metal ions) of the encapsulant layer 130 from being diffused into the semiconductor die 110 (e.g., made of silicon). Therefore, electrical performance of the semiconductor die 110 may be preserved, even after a long period of time.

Next, a method of manufacturing a semiconductor device 200 in accordance with various aspects of the present disclosure will be described. The semiconductor device 200, and the method of manufacturing thereof, may for example share any or all characteristics with the semiconductor device 100 and method of manufacturing thereof, shown in FIG. 1 and discussed herein. The following description will generally focus on differences between the semiconductor devices 100 and 200 according to the previous and present examples.

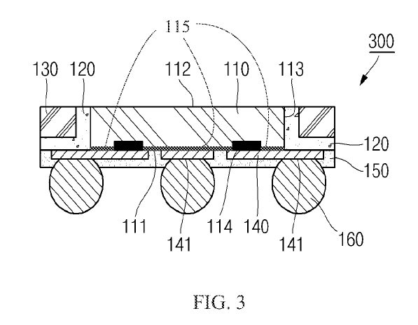

Referring to FIG. 2, such figure shows a cross-sectional view illustrating a semiconductor device 200 and method of manufacturing thereof, in accordance with various aspects of the present disclosure.

As illustrated in FIG. 2, a first dielectric layer 120 (e.g., a passivation layer) disposed on a second surface 112 of a semiconductor die 110 may be directly exposed to the outside through an encapsulant layer 130. For example, the encapsulant layer 130 formed on the first dielectric layer 120 disposed on the second surface 112 of the semiconductor die 110 (or, for example, the uppermost surface of the first dielectric layer 120) may be removed (e.g., by grinding and/or etching) or the encapsulant layer 130 may be originally formed without covering the second surface 112 of the semiconductor die 110, thereby allowing the first dielectric layer 120 disposed on the second surface 112 of the semiconductor die 110 to be exposed (e.g., exposed to outside of the encapsulant layer 130).

As described herein, the semiconductor device 200 according to various aspects of the present disclosure may readily transmit or emit heat generated by the semiconductor die 110 to the outside (or, for example, to an attached heat sink or cover). For example, as opposed to the example semiconductor device 100 of FIG. 1, the semiconductor device 200 may transfer heat from the second surface 112 of the semiconductor die 110 through only the first dielectric layer 120 instead of through both the first dielectric layer 120 and the encapsulant layer 130.

Referring to FIG. 3, such figure shows a cross-sectional view illustrating a semiconductor device 300 and manufacturing method thereof, in accordance with various aspects of the present disclosure. The semiconductor device 300 and the method of manufacturing thereof, may for example share any or all characteristics with the semiconductor device 100 and method of manufacturing thereof as shown in FIG. 1 and discussed herein and/or with the semiconductor device 200 and method of manufacturing thereof as shown in FIG. 2 and discussed herein.

As illustrated in FIG. 3, a second surface 112 of a semiconductor die 110 may be exposed to the outside through a first dielectric layer 120 (e.g., a passivation layer) formed on a third surface 113 of the semiconductor die 110. For example, the first dielectric layer 120 disposed on the second surface 112 of the semiconductor die 110 and/or the encapsulant layer 130 formed thereon may be removed (e.g., by grinding and/or etching) or both the first dielectric layer 120 and encapsulant layer 130 may be originally formed without covering the second surface 112 of the semiconductor die 110, thereby allowing the second surface 112 of the semiconductor die 110 to be exposed (e.g., exposed to the outside of the first dielectric layer 120 and the encapsulant layer 130).

As described herein, the semiconductor device 300 according to various aspects of the present disclosure may readily transmit or emit heat generated by the semiconductor die 110 to the outside (or, for example, to an attached heat sink or cover). For example, as opposed to the example semiconductor device 200 of FIG. 2, the semiconductor device 300 may transfer heat directly from the second surface 112 of the semiconductor die 110 instead of through the first dielectric layer 120. Also for example, as opposed to the example semiconductor device 100 of FIG. 1, the semiconductor device 300 may transfer heat directly from the second surface 112 of the semiconductor die 110 instead of through both the first dielectric layer 120 and the encapsulant layer 130.

In summary, various aspects of this disclosure provide a semiconductor device and a method of manufacturing thereof. While the foregoing has been described with reference to certain aspects and examples, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

1. A semiconductor device comprising:
a semiconductor die comprising:
a first die surface;
a second die surface opposite the first die surface; and
a third die surface extending between the first die surface and the second die surface;
a die dielectric layer on the first die surface, the die dielectric layer comprising a first die dielectric layer surface facing away from the semiconductor die and a second die dielectric layer surface facing the semiconductor die;
a first dielectric layer comprising:
a first dielectric layer portion on the third die surface and having a uniform thickness; and
a second dielectric layer portion that extends outwardly from the first dielectric layer portion and comprises a first surface that is coplanar with the first die dielectric layer surface;
an encapsulant layer on the first dielectric layer; and
a conductive layer on the first surface of the semiconductor die and on the second dielectric layer portion.

2. The semiconductor device of claim 1, wherein the first dielectric layer portion has a first thickness, and the second dielectric layer portion has a second thickness that is the same as the first thickness.

3. The semiconductor device of claim 1, wherein the die dielectric layer comprises an inorganic dielectric layer.

4. The semiconductor device of claim 3, comprising a second dielectric layer that comprises an organic dielectric layer that directly contacts the inorganic dielectric layer of the die dielectric layer.

5. The semiconductor device of claim 1, wherein the die dielectric layer is directly on the first die surface.

6. The semiconductor device of claim 1, wherein the first dielectric layer portion completely covers the third die surface.

7. The semiconductor device of claim 6, wherein the first dielectric layer comprises a third dielectric layer portion on the second die surface.

8. The semiconductor device of claim 7, wherein the third dielectric layer portion has a same thickness as the second dielectric layer portion.

9. The semiconductor device of claim 1, wherein the second die surface is exposed from the encapsulant layer and the first dielectric layer.

10. A semiconductor device comprising:
a semiconductor die comprising:
a top die surface;
a bottom die surface opposite the top die surface and separated from the top die surface by a die thickness; and
a side die surface extending between the top die surface and the bottom die surface;
a bond pad on the bottom die surface;
a die dielectric layer on the bottom die surface, the die dielectric layer comprising a top die dielectric layer surface facing the bottom die surface and a bottom die dielectric layer surface facing away from the bottom die surface; and
a first dielectric layer covering at least a portion of the side die surface and comprising:
a first horizontal dielectric layer portion above the semiconductor die and having a first thickness; and
a second horizontal dielectric layer portion laterally offset from the semiconductor die, comprising a bottom surface that is coplanar with the bottom die dielectric layer surface, and having a second thickness that is the same as the first thickness.

11. The semiconductor device of claim 10, wherein the first dielectric layer comprises a vertical dielectric layer portion comprising a first vertical dielectric layer side facing the side die surface, and a second vertical dielectric layer side opposite the first vertical dielectric layer side and facing away from the side die surface.

12. The semiconductor device of claim 11, wherein the vertical dielectric layer portion has a third thickness that is the same as the first thickness.

13. The semiconductor device of claim 10, wherein the second thickness is less than half of the die thickness.

14. A method of manufacturing a semiconductor device, the method comprising:
coupling a first die surface of a semiconductor die to a carrier, the semiconductor die comprising:
the first die surface;
a second die surface opposite the first die surface; and
a third die surface extending between the first die surface and the second die surface;
forming a first dielectric layer comprising a first dielectric layer portion formed on the third die surface and a second dielectric layer portion formed on an area of the carrier not covered by the semiconductor die, wherein the first dielectric layer portion has a uniform thickness;
forming an encapsulant layer on the first dielectric layer;
removing the carrier; and
forming a conductive layer on the first die surface and on the first dielectric layer.

15. The method of claim 14, wherein said coupling the first die surface of the semiconductor die to the carrier comprises positioning a die dielectric layer between the first die surface and the carrier, and wherein a surface of the die dielectric layer and a surface of the second dielectric layer portion are coplanar.

16. The method of claim 14, wherein the second dielectric layer portion has a thickness that is the same as the thickness of the first dielectric layer portion.

17. The method of claim 14, wherein the first dielectric layer portion completely covers the third die surface.

18. The method of claim 17, wherein the first dielectric layer comprises a third dielectric layer portion on the second die surface.

19. The method of claim 18, wherein the third dielectric layer portion has a thickness that is the same as the thickness of the second dielectric layer portion.

20. The method of claim 14, wherein the second die surface is exposed from the encapsulant layer and the first dielectric layer.
